(19) United States
(12) Patent Application Publication
(10) Pub. No.: US 2018/0358498 A1
(43) Pub. Date: Dec. 13, 2018

(54) PHOTOVOLTAIC MODULE

(71) Applicant: Euro Com Project Nowinski, Zamroczynska Sp. j., Mogilno (PL)

(72) Inventors: Lukasz Nowinski, Mogilno (PL); Dariusz Zamroczynski, Mogilno (PL)

(21) Appl. No.: 16/003,410

(22) Filed: Jun. 8, 2018

(30) Foreign Application Priority Data
Jun. 8, 2017 (PL) P.421831

(51) Int. Cl. H01L 31/05; H01L 31/0224; H01L 31/028

(52) U.S. Cl. CPC H01L 31/0512; H01L 31/028; H01L 31/022425

(57) ABSTRACT

A photovoltaic module is shown. The module is made up of a set of cells. Each cell comprises silicon while a graphene electrode is used for the connections. The electrode comprises a graphene grid or strips and is set in a polymer layer applied to the cells from both sides.

### PRIORITY CLAIM

The instant application claims priority to Polish Patent Application P.421831 filed on Jun. 8, 2017, presently pending.

### FIELD OF THE INVENTION

The subject of the invention is a photovoltaic module, specifically its construction and way of connecting of the individual cells and elements that allow for maximal current efficiency, durability and resistance to the weather conditions.

### BACKGROUND OF THE INVENTION

Use of solar radiation in both, direct heating of rooms and buildings as well as electric energy generation by means of photovoltaic cells is more and more common.

Photovoltaic solar cells are basically known since the 80's of the twentieth century. However, they are a more and more common source of electric energy thanks to more and more effective and cheaper methods of producing the solar panels and modules. A single cell is a semiconducting P-N or N-P plate wish an electrode made of metal, which is created on upper and lower surfaces of a plate. Electrodes of the upper (or frontal) side of the photovoltaic cells are usually formed as a group of endings connected by one or more rails. On the other hand, electrodes on the lower or back side of photovoltaic modules are formed as a continuous layers. Such a solutions are know from US patents such as U.S. Pat. No. 4,434,318 or U.S. Pat. No. 4,443,652.

In principle, the biggest disadvantage of such a solution is the fact that it is strongly dependent on weather and time of the year when it comes to energy yield. Photovoltaic modules are coupled in a form of boards and together create PV modules, also called panels. The photovoltaic cells are joined serially and in parallel cater for adequate voltage and current supply.

A module's efficiency in practice is not in 100% directly proportional to efficiency of each of individual modules coupled serially into the electrical matrix. When converting cells into panels the losses amount to up to 3-5% when using traditional “bus bar” technology. An example of such a solution is the panel description disclosed in European application EP3136448 A1.

### SUMMARY OF THE INVENTION

The aim of this invention is to eliminate the above flaws.

The essence of the solution is connecting individual cells with a graphene electrode in form of graphene network or graphene strips set in the polymer foil applied directly on both the cell on the exposed side as well as from the bottom.

### BRIEF DESCRIPTION OF DRAWINGS

The invention together with the above and other objects and advantages will be best understood from the following detailed description of the preferred embodiment of the invention shown in the accompanying drawings, wherein:

FIG. 1 depicts a schematic overview of a module; and

FIG. 2 depicts an overview of joining of several layers of a module.

### DETAILED DESCRIPTION OF THE INVENTION

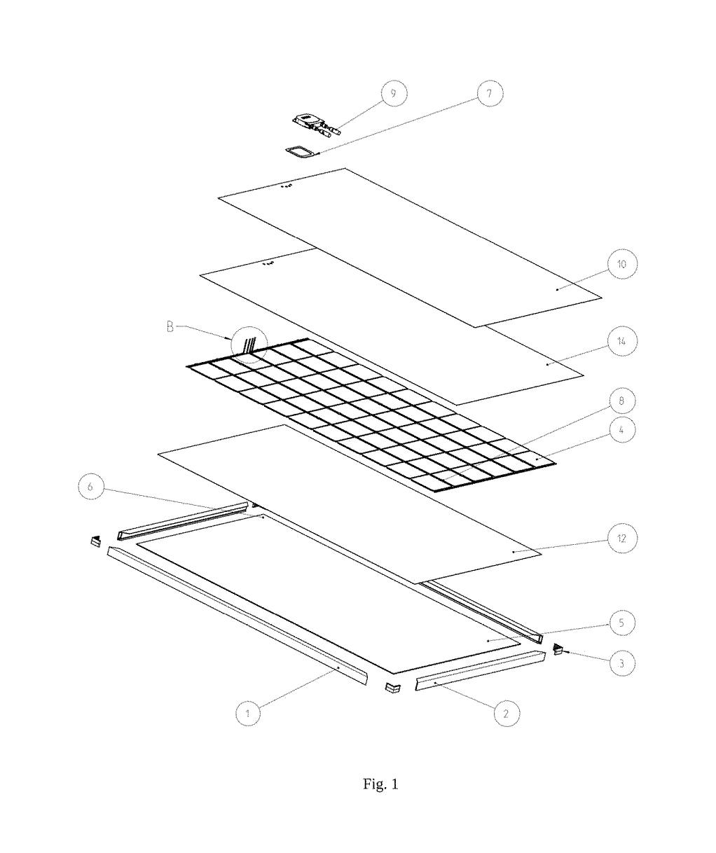

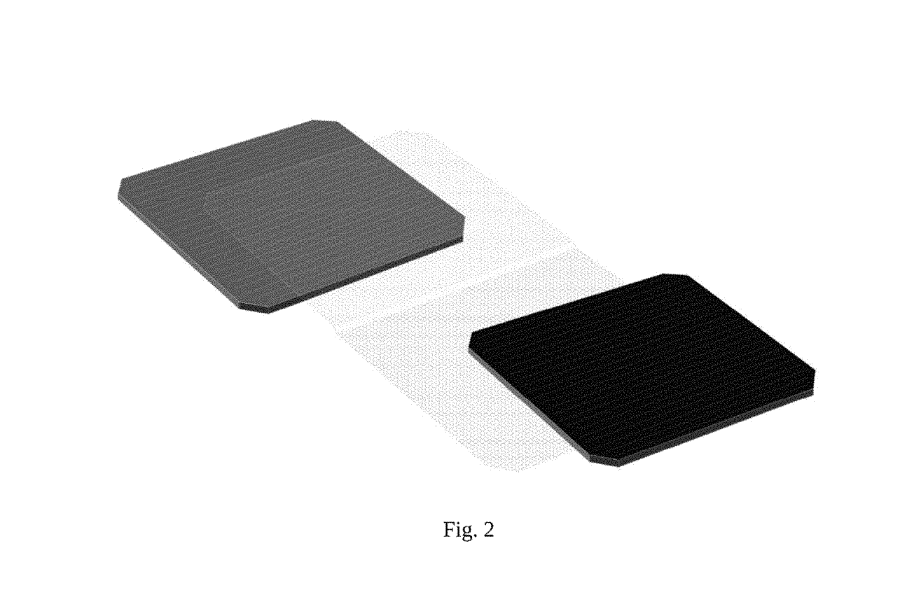

The invention is depicted in the example embodiment in the figures, but alternative embodiments are envisioned not restricted to the figures. FIG. 1 depicts a schematic of modules built by separating the elements, together with their layout after mounting, according to the invention. FIG. 2, on the other hand, shows schematics of joining graphene foil with photovoltaic cells.

The module consists of frames 1, 2 coupled with corners 3 holding the photovoltaic cells 4 covered with hardened glass sheet 5 with the anti-reflective layer 6. From the surface graphene electrodes 8 through the B connector the electric energy reaches the collector 9 joined through the seal 7. Photovoltaic cells modules are covered with EVA or TPO foil or film 12, 14 on both sides. From the bottom side, the panel is secured with a layer of silicone or PET film 10.

The created silico-graphene structure is far more resistant and durable due to the fact that silicone itself is twenty times more durable than steel. The PV modules created according to the invented technology have longer life expectancy and small vulnerability to micro fractures.

Moreover, the pane allows for gaining more than 50% more energy thanks to graphene matrix's better reaction to the scattered light and in the situations when the matrix is in the shadow. Connection of single cells with a network of micro fibers lowers module's sensitivity to the shading is minimal and the loss on electricity production is limited to a small area near the shaded place, not to the entire surface of the active module.

The photovoltaic module is characterized by the fact that connections of the individual silicon cells is done with use of graphene electrode in the form of full graphene grid or graphene strips set in polymer foil applied directly onto the cell from both sides, on the exposed side and on the underside.

The embodiment of the invention in which an exclusive property or privilege is claimed is defined as follows:

1. A photovoltaic module comprising:
a set of silicon cells interconnected by connections wherein connections of the individual silicon cells with use of a graphene electrode in form of full graphene grid or graphene strips set in a polymer layer applied directly onto each cell on both sides, on the exposed side and on an underside of said set of cells.

2. The module of claim 1 wherein said connections comprise serial and parallel connections.

3. The module of claim 2 wherein said polymer layer comprises EVA or TPO.

4. The module of claim 3 wherein said polymer layer comprises a film.
